(19) United States
(12) Patent Application Publication
(10) Pub. No.: US 2016/0080666 A1
(43) Pub. Date: Mar. 17, 2016

(54) TEST AND MEASUREMENT SYSTEM WITH REMOVABLE IMAGING TOOL

(71) Applicant: Fluke Corporation, Everett, WA (US)

(72) Inventors: Michael D. Stuart, Issaquah, WA (US); Terry G. Morey, Renton, WA (US); Paul H. Heydron, Everett, WA (US); Jeffrey E. Worones, Seattle, WA (US); Michael A. Schoch, Granite Falls, WA (US); Matthew D. Rabdau, Bothell, WA (US)

(21) Appl. No.: 14/855,884

(22) Filed: Sep. 16, 2015

Related U.S. Application Data
(60) Provisional application No. 62/051,903, filed on Sep. 17, 2014.

(51) Int. Cl. H04N 5/33; H04N 5/225; G01R 15/12

(52) U.S. Cl. CPC H04N 5/332; G01R 15/125; H04N 5/225

(57) ABSTRACT

Test and measurement systems can include a test and measurement tool configured to generate measurement data representative of at least one parameter of an object under test and an imaging tool configured to generate image data representative of a target scene. The imaging tool can be removably attachable to the test and measurement tool. The test and measurement system can include a communication link that can provide communication between the test and measurement tool and the imaging tool. The communication link can facilitate one or both of communication of image data to the test and measurement tool and measurement data to the imaging tool. Systems can include a display in communication with at least one of the test and measurement tool or the imaging tool for presenting at least one of image data or measurement data to a user.

### CROSS-REFERENCES

This application claims the benefit of U.S. Provisional Application No. 62/051,903, filed Sep. 17, 2014, the content of which is hereby incorporated by reference in its entirety.

### BACKGROUND

Various information regarding parameters of system components may be useful in analyzing individual component's performance, operating conditions, lifespan, and other various aspects. Some such information includes measureable quantities, such as a current, voltage, power, impedance, vibration, and the like. Analysis of components of a system may provide insight into ways the system may be improved, for example, by repairing or replacing faulty or otherwise non-optimal components. Various test and measurement tools are capable of performing such measurements, and are often used in analyzing such components.

In some examples, additional information may be helpful in analyzing such components. For example, imaging techniques, such as infrared imaging, may provide useful additional information. Infrared imagery of a system or components thereof can provide thermal patterns of the scene, highlighting temperature abnormalities in system components. Such imagery may be useful in diagnosing similar or different issues that may be detected or otherwise analyzed using standard test and measurement tools as discussed above.

In order to take advantage of the benefits of measurements using various test and measurement tools and also infrared imagery, a user set to analyze the system must often carry several pieces of equipment for performing desired analysis. In addition, the user must take care to ensure that any recorded measurement data (e.g., from one or more test and measurement tools) is associated with the appropriate equipment and correlated to other measurement data from other test tools.

### SUMMARY

Embodiments of the invention are directed to systems and methods for analyzing properties of an object under test. Systems can include a test and measurement tool capable of performing at least one measurement to acquire measurement data representative of at least one parameter of an object under test. System can include an imaging tool capable of detecting radiation from a target scene and producing image data representative of a target scene. The imaging tool can be sensitive to any appropriate range of radiation wavelengths, such as visible light and infrared radiation. In some examples, the imaging tool can one or both of an infrared sensor array for generating infrared image data and a visible light sensor array for generating visible light image data. In some embodiments, the imaging tool can be removably attachable to the test and measurement tool. Alternatively, in some embodiments, the imaging tool may be fixedly attached to the test and measurement tool.

Systems can include a communication link capable of providing communication between the test and measurement tool and the imaging tool. Thus, in some embodiments, the imaging tool can receive measurement data from the test and measurement tool via the communication link. Additionally or alternatively, the test and measurement tool can receive image data from the imaging tool via the communication link. In some embodiments, the system includes a display in communication with one or both of the test and measurement tool and the imaging tool. The display may be integral to any one or more of the imaging tool, the test and measurement tool, or an external device. In some embodiments, the system may communicate one or both of image data and measurement data to the display for presentation to a user. In some examples, the system can include a user interface to provide the user various options for acquiring and/or displaying data. Communication between various system components (e.g., the imaging tool, the test and measurement tool, a display, an external device, etc.) can be wired or wireless communication.

### BRIEF DESCRIPTION OF THE DRAWINGS

FIGS. 1A-C are views of exemplary systems including a test and measurement tool and an imaging tool

FIG. 2 is an exemplary schematic diagram of a test and measurement tool comprising a variety of components.

FIG. 3 shows an example block diagram of an imaging tool configured for receiving electromagnetic radiation according to some exemplary systems.

FIGS. 4A and 4B show exemplary optical configurations of imaging tools including multiple sensor arrays.

FIG. 5 is an exemplary diagram illustrating communication between various system components.

FIG. 6 is an exemplary display showing combined image and measurement data.

### DETAILED DESCRIPTION

Embodiments of the invention generally relate to a test and measurement system including a test and measurement tool and a removable imaging tool. The test and measurement tool can include the ability to measure or otherwise determine a characteristic of an object under test. Exemplary test and measurement tools can include, but are not limited to, digital multimeters, current measurement tools, power quality tools, vibration tools, portable oscilloscope tools, laser alignment tools, ultrasonic test tools, insulation resistance testers, multi-function electrical test tools, single-function electrical test tools, contact temperature measurement tools, humidity measurement tools, air-flow measurement tools, air temperature measurement tools, air quality and particulate measurement tools.

Various test and measurement tools can be configured to perform one or more primary functions. In some examples, the primary function of a test and measurement tool can include performing a primary measurement. For instance, a primary function of some current measurement tools can include measuring an electrical current. It will be appreciated that a test and measurement tool may have more than one primary function. For example, a digital multimeter (DMM) may include several primary functions, such as measuring current, voltage, and resistance, for example.

In some examples, a test and measurement system can include at least one test and measurement tool and at least one imaging tool configured to acquire image data of a target scene. In various embodiments, the imaging tool may include one or more cameras, sensors, or other optical component capable of receiving electromagnetic radiation and generating electrical signals representative of the received radiation. Portions of the imaging tool may be sensitive to one or more wavelengths or wavelength bands. For example, in some embodiments, the portions of the imaging tool can be capable of detecting any combination of visible light (VL), near infrared (NIR), short-wavelength infrared (SWIR), long-wavelength infrared (LWIR), terahertz (THz), ultraviolet (UV), X-ray, or other wavelengths.

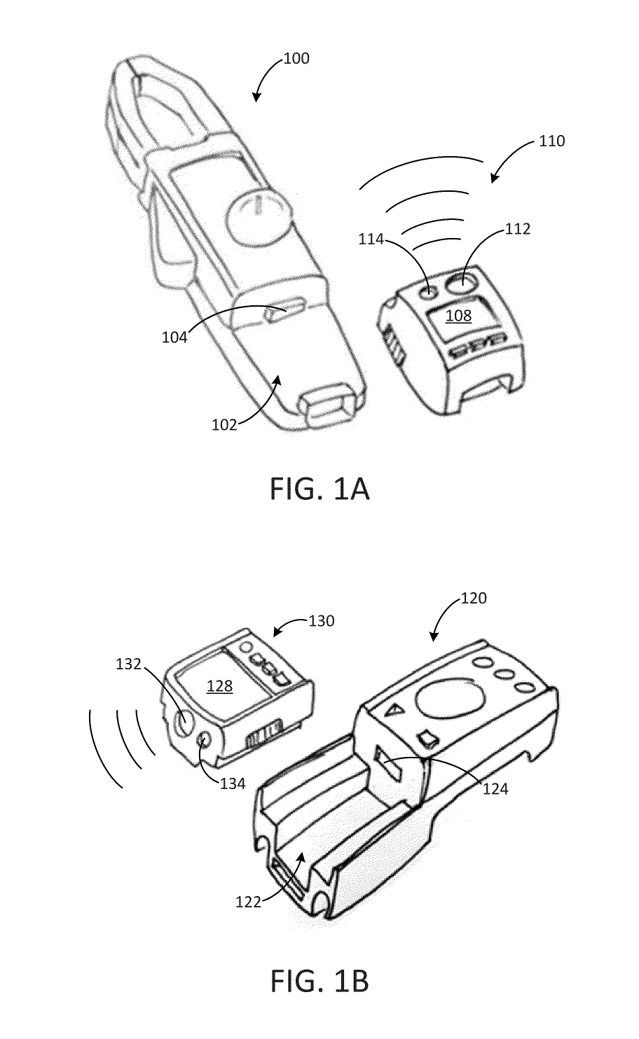

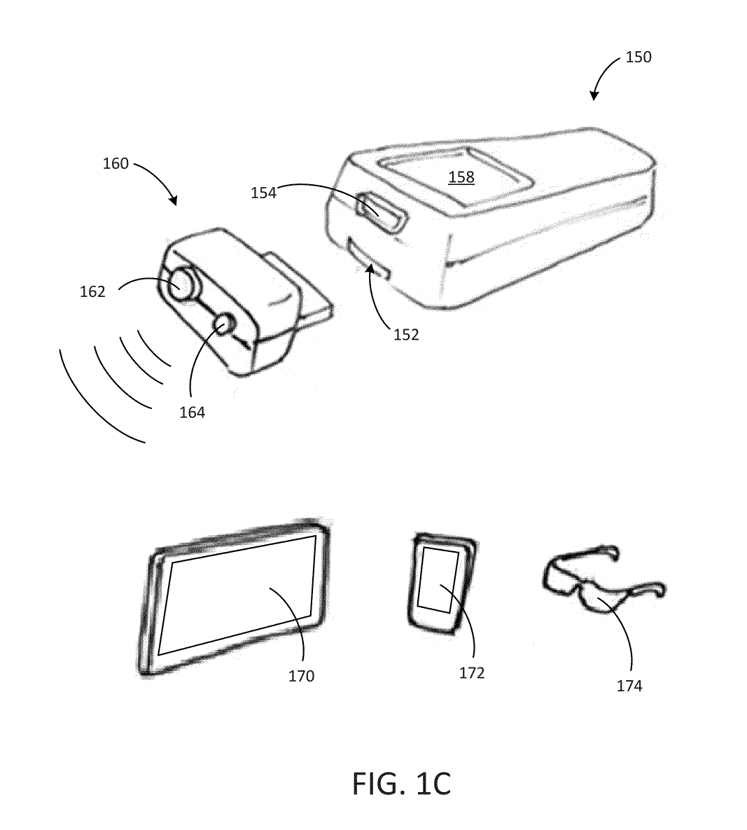

FIG. 1A is a view of an exemplary system including a test and measurement tool and an imaging tool. FIG. 1A includes a test and measurement tool 100 and an imaging tool 110. As described, the test and measurement tool 100 can be configured to perform at least one primary function, such as measuring a current (e.g., a current clamp). The illustrated imaging tool 110 includes an infrared (IR) camera 112 and a visible light (VL) camera 114, though it will be appreciated that various imaging tools such as 110 can include any combination of appropriate detectors. In some examples, the imaging tool 110 can include a display 108 for visual presentation of one or both of, for example, IR and VL image data. In some embodiments, the test and measurement tool 100 can removably receive the imaging tool 110 at a receiving portion 102 of the test and measurement tool 100. In various embodiments, the imaging tool 110 can be secured to the test and measurement tool 100 in any number of ways, for example, via a press fit, snap fit, clip, magnet, hook and loop fastener, or the like.

In some examples, the test and measurement tool 100 can include a communication port 104 for communicating with the imaging tool 110. In various embodiments, communication port 104 can communicate with the imaging tool 110 when the imaging tool 110 is received by the test and measurement tool 100, such as via a physical connection. In some examples, the communication port 104 is capable of wireless communication such that the test and measurement tool 100 may communicate with the imaging tool 110 when the imaging tool 110 is separate from the test and measurement tool 100. Communication port 104 can facilitate any known form of communication between the imaging tool 110 and the test and measurement tool 100, including wired or wireless communication (e.g., radio frequency (RF) communication, infrared (IR) communication, serial communication, Wi-Fi, Zigbee, Bluetooth, etc.). In some embodiments, communication port 104 provides two-way communication between the test and measurement tool 100 and the imaging tool 110.

During exemplary operation of a system such as that in FIG. 1A, the imaging tool 110 includes an IR 112 and a VL 114 camera and is positioned separate from the test and measurement tool 100 and proximate an object under test such that the object is within the field of view of at least one of the cameras 112, 114. The test and measurement tool 100 can be configured to measure at least one parameter related to the object under test, such as a current flowing through the object. The test and measurement tool 100 can measure the at least one parameter while the imaging tool 110 captures image data of the object under test.

The test and measurement tool 100 and imaging tool 110 can be in communication to share data, such as via communication port 104. For instance, in some examples, the imaging tool 110 can communicate received image data to the test and measurement tool 100 for display on the test and measurement tool. Additionally or alternatively, the test and measurement tool 100 can communicate the at least one parameter to the imaging tool 110 for display. Communication can be accomplished via, for example, IR communication (e.g., IrDA), Bluetooth communication, or other appropriate wired or wireless data transmission. Resultantly, a combined display of image data and the at least one parameter can be presented at one or both of the test and measurement tool 100 and the imaging tool 110.

In some examples, communication port 104 is positioned proximate a receiving portion 102 of the test and measurement tool 100. In some such embodiments, the imaging tool 110 may be attached to the receiving portion 102 of the test and measurement tool 100 and engage the communication port 104 of the test and measurement tool 100. Thus, the imaging tool 110 may be capable of communicating with the test and measurement tool 100 when received at the receiving portion 102 thereof. In some examples, communication between the imaging tool 110 and the test and measurement tool 100 via communication port 104 may be automatically initiated upon attaching the imaging tool 110 to the receiving portion 102 of the test and measurement tool 100.

FIG. 1B is a view of another exemplary system including a test and measurement tool and an imaging tool. The test and measurement tool 120 and imaging tool 130 of FIG. 1B are similar to those of FIG. 1A, and may be configured to include many similar features and perform similar functions. For instance, in the illustrated example, imaging tool 130 may include an infrared camera 132 and a visible light camera 134, and a display 128 for presentation of acquired image data. The test and measurement tool 120 may include a receiving portion 122 for receiving imaging tool 130, and a communication port 124 for communicating therewith. In the illustrated embodiment of FIG. 1B, the receiving portion 122 of the test and measurement tool is configured to slidably receive the imaging tool 130. In some examples, imaging tool 130 can slide into receiving portion 122 of test and measurement tool 120, and in some instances, can be secured in place via any number of appropriate attachment mechanisms. In various embodiments, imaging tool 130 and test and measurement tool 120 can interact and communicate in any of the ways as described with regard to imaging tool 110 and test and measurement tool 100.

FIG. 1C is a view of still another exemplary system including a test and measurement tool and an imaging tool. In the illustrated embodiment, test and measurement tool 150 includes a communication port 154 and a display 158. In some examples, display 158 can be used to display at least one parameter measured or detected by the test and measurement tool 150. The test and measurement tool 150 can be in communication with imaging tool 160, which can include, for example, infrared camera 162 and visible light camera 164 for receiving radiation from a target scene and generating image data representative thereof. In some embodiments, the test and measurement tool 150 can be configured to collect auxiliary information (e.g., image data) regarding an object under test via communication port 154. Such auxiliary information can include one or both of IR and VL image data (e.g., from IR camera 162 or VL camera 164) or other data regarding the object under test.

Communication port 154 can include, for example, IR communication or any other appropriate known communication. Data can be communicated back and forth between the imaging tool 160 and the test and measurement tool 150. In some instances, image data acquired by the imaging tool 160 can be presented on the display 158 of the test and measurement tool 150 in conjunction with or as an alternative to the at least one parameter measured or detected by the test and measurement tool 150.

Test and measurement tool 150 includes a receiving portion 152 disposed on the front surface for releasably engaging imaging tool 160. In some such examples, imaging tool 160 can be secured to test and measurement tool 150 and communicate image data thereto, for example, via communication port 154. Test and measurement tool 150 can display image data on the display 158. In some examples, the image data stream from the imaging tool 160 to the test and measurement tool 150 can be substantially real-time. Thus, a user may manipulate the combination test and measurement tool 150 and imaging tool 160 in order to observe a live image of a target scene via display 158.

In some embodiments, test and measurement tool 150 or the imaging tool 160 can communicate data to one another or to an external device for display or other storing or processing. FIG. 1C illustrates exemplary external devices configured to receive data from one or more of the test and measurement tool 150 and the imaging tool 160. As shown, in some examples, tablets 170, smartphones 172, or smart glasses 174 capable of any combination of receiving, displaying, and processing data can communicate with one or both of test and measurement tool 150 and imaging tool 160. Such external devices can be used to perform at least one of displaying and analyzing data received from the test and measurement tool 150 or the imaging tool 160. Additional external devices capable of receiving data from one or more of the test and measurement tool and imaging tool can include PCs or other appropriate computing devices.

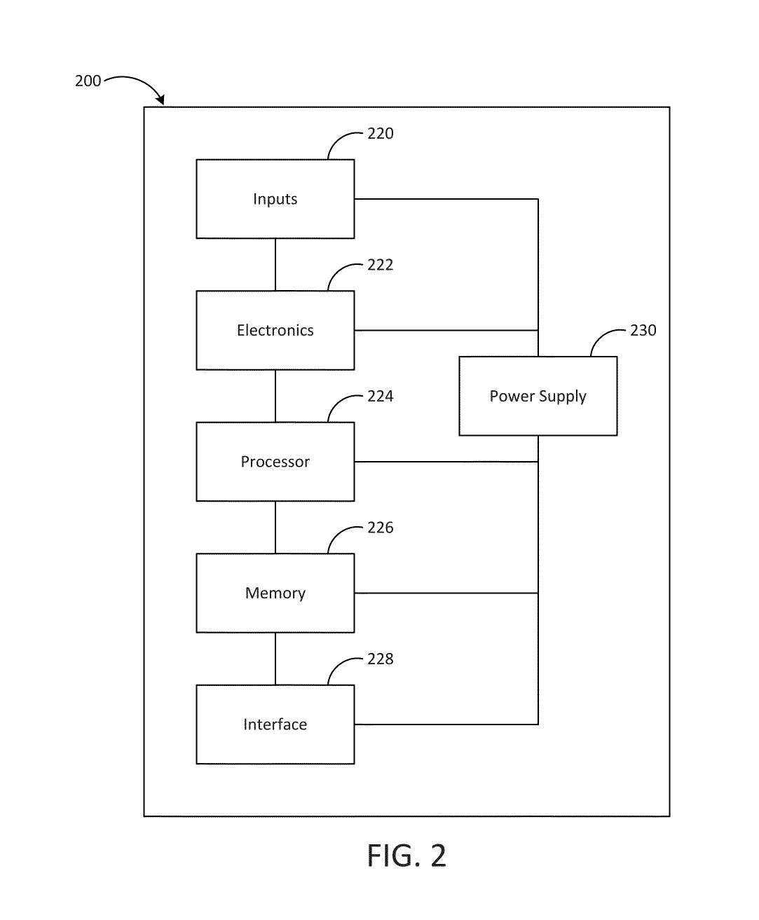

FIG. 2 is an exemplary schematic diagram of a test and measurement tool comprising a variety of components. In the illustrated example, the test and measurement tool 200 may include one or power supplies 230 for providing electrical power to any of a variety of system components for performing a variety of tasks, such a performing one or more primary functions. In some embodiments, the one or more power supplies 230 may include one or more batteries. Additionally or alternatively, the test and measurement tool 200 may be capable of running on AC power, e.g., from a standard wall receptacle. In some such embodiments, one or more batteries of the test and measurement tool 200 may be charged while the tool 200 is operating on or otherwise plugged into an AC power source.

The test and measurement tool may include one or more inputs 220 configured to interface with an object under test for performing a measurement of a parameter thereof. In various examples, the one or more inputs 220 may include any appropriate input for performing a measurement of a parameter of a device under test. The one or more inputs 220 may provide a signal indicative the parameter of the object under test to any combination of electronics 222 and a processor 224 for further processing of the signal. In some examples, the test and measurement tool 200 includes a memory 226 for storing information indicative of one or more parameters of a device under test.

In some embodiments, test and measurement tool 200 may include an interface 228 for interacting with a user. In some examples, interface may include one or more controls for receiving user inputs. Controls may include, for example, buttons, switches, knobs, touch screens, etc. In some embodiments, a user may initiate a measurement or other test and measurement tool 200 function using controls. Additionally or alternatively, the interface may include a display for communicating information to a user. For example, the display may present a user with selectable options, such as various functions selectable by the user via controls. Additionally or alternatively, the display may be configured to present the results of one or more measurements performed by the test and measurement tool for observation by a user.

In some examples, interface 228 may provide an interface with additional equipment. For example, in some embodiments, interface 228 can provide a communication interface between the test and measurement tool 200 and an imaging tool (e.g., 110) or an external device (e.g., smartphone, tablet, etc.). In various embodiments, interface 228 can be used to export received measurement data, such as from inputs 220, or a processed result, for example, from processor 224.

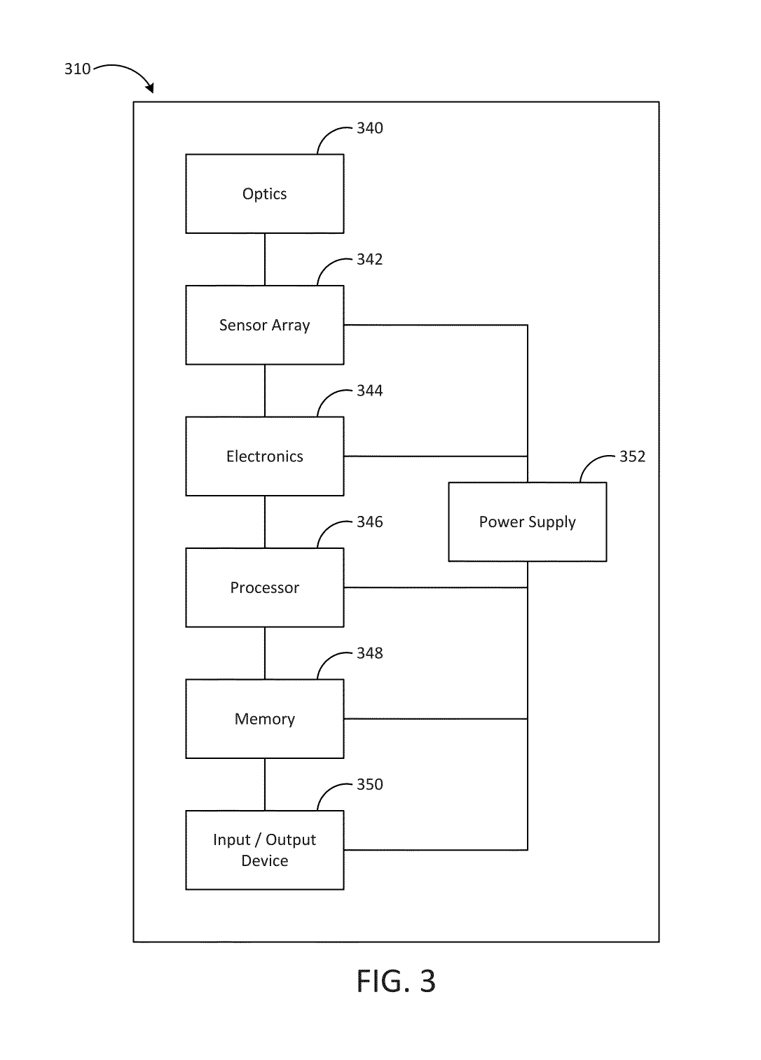

FIG. 3 shows an example block diagram of an imaging tool configured for receiving electromagnetic radiation according to some exemplary systems. In the illustrated embodiment, imaging tool 310 includes optics 340, a sensor array 342, electronics 344, one or more processors 346, memory units 348, input/output devices 350, and a power supply 352.

The optics 340 can include optics for focusing, deflecting, and/or reflecting electromagnetic radiation from a target object onto the sensor array 342. In some examples, the sensor array 342 may include an infrared sensor array sensitive to infrared radiation. An imaging tool including such an infrared sensor array may be used to make non-contact temperature measurements.

In such embodiments, the infrared sensor array 342 can include one or more thermal detectors such as microbolometers or thermopiles, or could be composed of photon detectors such as photodiodes or phototransistors, or other thermal or photon detection device. In some examples, an infrared sensor array may include a single detector, for instance, for determining a spot temperature within a target scene. Alternatively, an infrared sensor array may comprise a plurality of such detectors for acquiring one or both of a spot temperature (e.g., via an average value of sensor array sensors) and a two-dimensional infrared image.

One of skill in the art will recognize that various sensor arrays (e.g. photon sensor arrays) can be used, and can be used in combination with one or more infrared sensor arrays. In some examples, the sensor array is fixed within the imaging tool 310 to provide a more durable device having fewer moving and moveable parts. In various examples, the size and positioning of the detector depends on the characteristics of the optical system (e.g., the relationship between optics 340 and sensor array 342). In some embodiments, the detector is generally circular having a diameter of 0.5 mm to 3 mm. However detectors of any size and shape should be considered within the scope of the invention. The detector produces a signal as a function of the radiation or other scene data imaged thereupon. These signals can be processed by known methods to indicate a temperature or other metric indicated via the received radiation.

A person of skill in the art will recognize that many materials and materials technologies may be suitable for use in an infrared sensor array. In some examples, the infrared sensor array 342 responds to infrared radiation ranging from approximately 0.7 microns to approximately 30 microns and can have a peak sensitivity within this range. The electronics 344 receive the output signals from the sensor array 342 and pass them to the processor 346 for analysis.

When an infrared sensor assembly is used, the processor 346 can be used to run infrared thermometer applications including, but not limited to, deciding if the target object sufficiently fills the field of view, and averaging output signals for a period of time to reduce the impact of noisy measurements on the accuracy of the measured temperature. In the case of alternative sensor arrays (e.g., sensitive to one or more of visible light, ultraviolet light, X-rays, etc.), the processor 346 may be used to run corresponding imaging applications.

Memory 348 can include but is not limited to, RAM, ROM, and any combination of volatile and non-volatile memory. A power supply 352 can include, but is not limited to, a battery, a parasitic energy system (e.g., an inductive system), and components for directly receiving AC power. The power supply 352 can provide power to the sensor array 342, electronics 344, processor 346, memory 348, and/or input/output devices 350. An input/output device 350 can include, but is not limited to, triggers to start and stop the image capture, visual displays, speakers, and communication devices that operate through wired or wireless communications.

For instance, in some examples, the input/output device 350 of the imaging tool 310 can include a display capable of displaying an image produced from data conveyed or captured by one or more sensor arrays 342. In some examples, the display can be further configured to show other data, for instance, data from the test and measurement tool (e.g., via communication port 104) or other external sources.

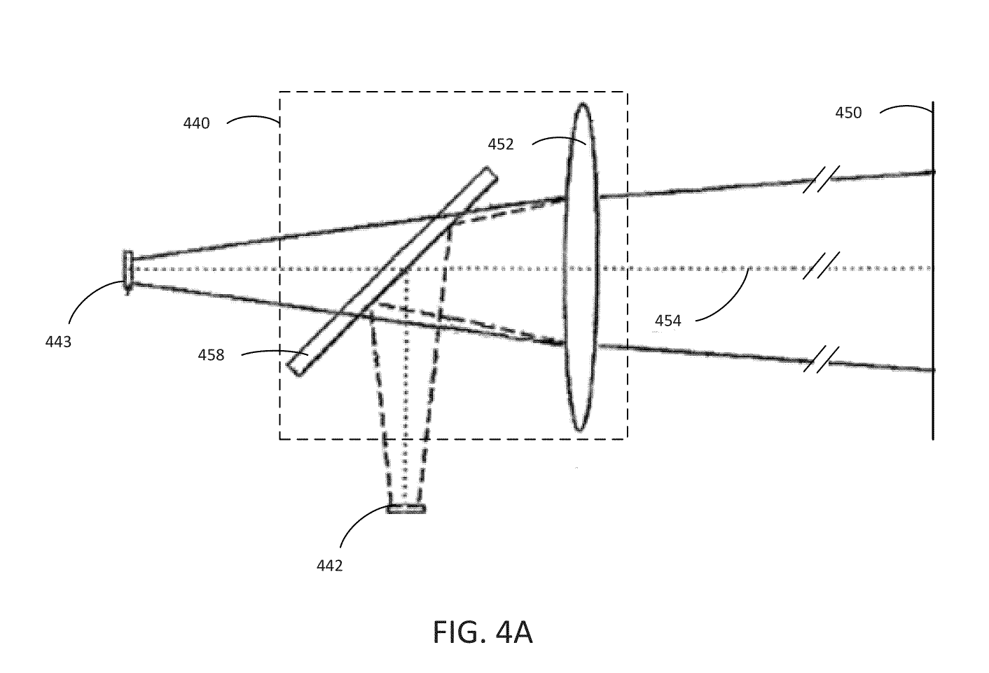

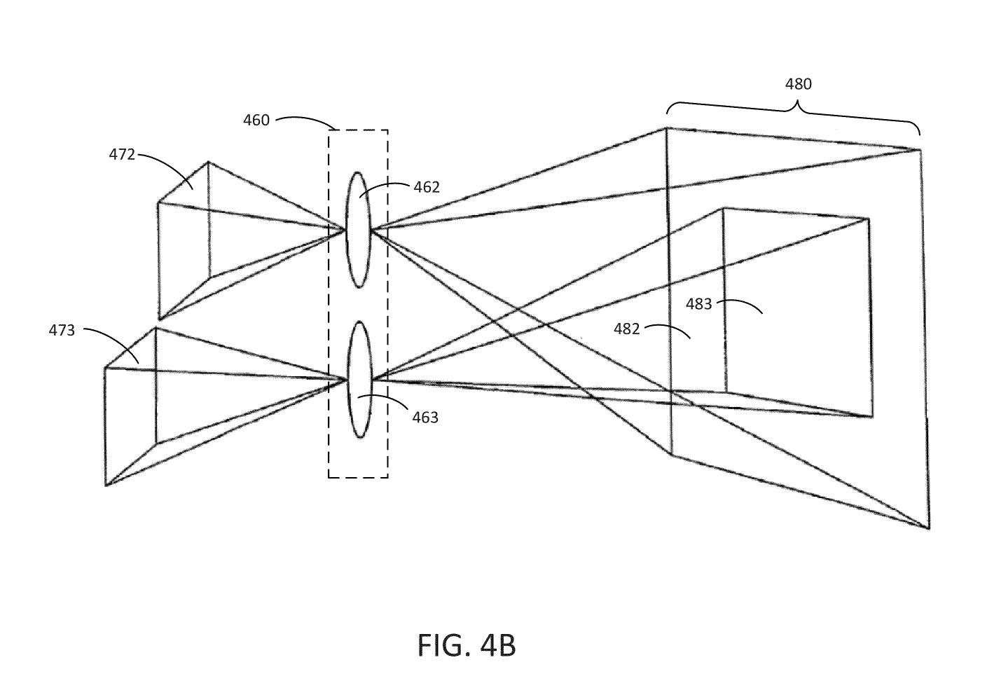

In some examples, the imaging tool includes more than one sensor array. For instance, a first sensor array may be sensitive to a first band of wavelengths (e.g., infrared radiation) while a second sensor array may be sensitive to a second band of wavelengths (e.g., visible light radiation). FIG. 4A is an exemplary optical configuration of an imaging tool including multiple sensor arrays. In some such examples, optics 440 of an imaging tool (e.g., 110) may include a lens 452 and a beam splitter 458. In the illustrated embodiment, the lens 452 receives radiation from a target scene 450 and directs the radiation toward the beam splitter 458. As shown, the beam splitter 458 is positioned at an angle relative to the optical axis 454 such that a portion of the radiation entering the imaging tool is reflected onto a first sensor array 442. The unreflected portion of the radiation passes through the beam splitter 458 and onto the second sensor array 443 which has been positioned generally concentrically about the optical axis 454. In this embodiment, the beam splitter 458 has been oriented at approximately 45 degrees relative to the optical axis 454 causing the first sensor array 442 to be positioned approximately 90 degrees relative to the optical axis 454.

Beam splitter 458 can comprise any of a variety of beam splitters known in the art. For example, the beam splitter may be configured to reflect IR radiation and transmit visible light radiation, or vice versa, in order to direct wavelengths in the appropriate band to its corresponding sensor array. Similarly, sensor arrays 442, 443 may include arrays sensitive to a variety of wavelengths. Such arrays may be sensitive to similar, overlapping, or dissimilar wavelengths or wavelength ranges.

FIG. 4B show an alternative approach to an imaging tool including a plurality of sensor arrays. In the illustrated embodiment, imaging tool includes parallel sensor arrays 472 and 473. In some embodiments, sensor arrays 472 and 473 are sensitive to different wavelengths of radiation. For example, sensor array 472 may be a visible light sensor array while sensor arrays 473 may be an infrared sensor array. Optics 460 comprising senses 462 and 463 may be used to focus radiation from a target scene 480 onto sensor arrays 472 and 473, respectively. In the illustrated embodiment, lens 462 is configured to focus radiation from portion 482 of target scene 480 onto sensor array 472. Similarly, lens 463 is configured to focus radiation from portion 483 of target scene 480 onto sensor array 473. In the illustrated example, portion 483 of the target scene 480 is contained within portion 482 of the target scene 480. The relationship of the portions of the target scenes imaged by sensing arrays 472 and 473 may be determined by the placement of the sensor arrays, placement of the optics, optical properties of the optics, and the like. As shown in FIG. 4B, multiple sensor arrays may be arranged in a parallel configuration without requiring the beam splitter 458 of FIG. 4A. However, it will be appreciated that many configurations may be used to detect radiation from a target scene (e.g., 450, 480) using a plurality of sensor arrays in a single imaging tool.

As described, the imaging tool can include one or more optical components (e.g., one or more sensor arrays) capable of generating image data of a particular range or ranges of wavelengths. In some examples, the two or more such optical components are configured to generate image data representative of at least partially overlapping target scenes. For instance, as shown in FIG. 3, the imaging tool may include a plurality of sensor arrays configured to receive incident electromagnetic radiation from a target scene and generate image data representative of the target scene. The target scene represented by the image data of the plurality of sensor arrays may at least partially overlap. In some such examples, the plurality of sensor arrays includes a visible light sensor array and an infrared sensor array.

In some examples, the imaging tool can include one or more wireless radio components for communication with the test and measurement tool, additional test tools, an external device, or any combination thereof. In some embodiments, one or both of the test and measurement tool (e.g., 100) and the imaging tool (e.g., 110) can include one or more wireless radio components for communicating a measured at least one parameter (e.g., from the test and measurement tool), image data (e.g., from the imaging tool), or both to an external device. External devices may include a computer, a smart device (e.g., smartphone, tablet, mini-tablet, smart watch, etc.), PCs, monitors, recording devices, heads-up displays, projected displays, or small displays in glasses, or personal protective equipment such as face shields, helmets, or bump caps. In some examples, external device may refer to a central server. Information may be communicated to the central server, for example, over a Wi-Fi or other internet connection. The external device may be used for any combination of displaying, saving to memory, and processing one or both of the at least one parameter and the image data.

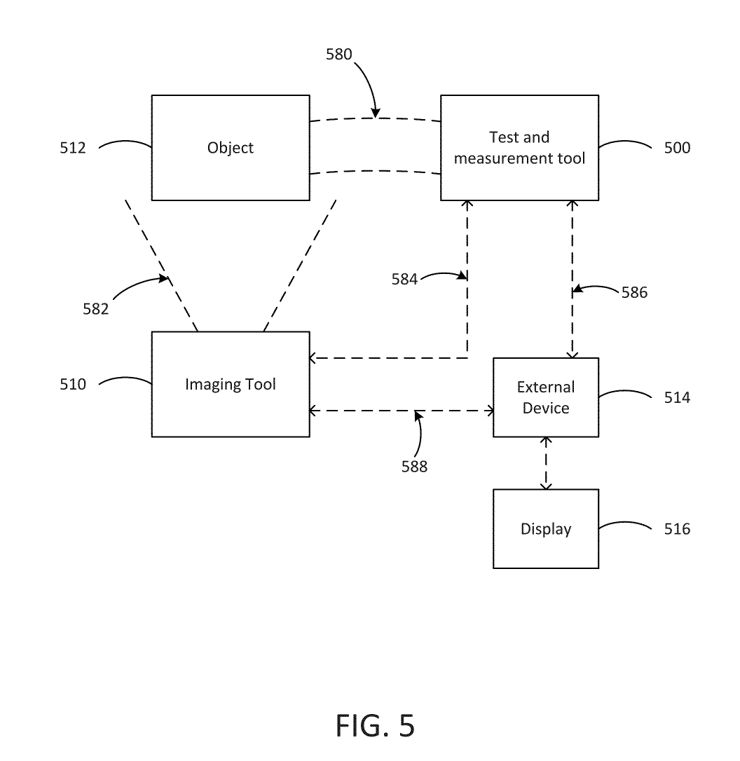

FIG. 5 is an exemplary diagram illustrating communication between various system components. In the illustrated example, test and measurement tool 500 is configured to measure one or more parameters of object 512 via connection 580. Connection 580 may be a wired or wireless connection. The test and measurement tool 500 is configured to generate measurement data representative of the at least one parameter of the object 512. In an exemplary embodiment, test and measurement tool 500 can include a DMM configured to measure the voltage across object 512 via a wired connection 580.

Imaging tool 510 is positioned proximate object 512 such that object 512 is in the field of view 582 of imaging tool 510. Imaging tool 510 can be configured to generate image data representative of the object 512. In an exemplary embodiment, imaging tool 510 includes an infrared sensor array and is configured to generate infrared image data representative of the heat pattern of object 512.

As shown, imaging tool 510 can communicate with test and measurement tool 500 via communication link 584. Communication link 584 may include one- or two-way communication between imaging tool 510 and test and measurement tool 500. In some examples, imaging tool 510 may communicate image data to test and measurement tool 500 via communication link 584. Additionally or alternatively, test and measurement tool 500 can communicate measurement data to the imaging tool 510 via communication link 584. One or both of test and measurement tool 500 and imaging tool 510 can be configured to display one or both of the measurement data and the image data associated with object 512.

As shown in the illustrated embodiment, an external device 514 can communicate with one or both of imaging tool 510 and test and measurement tool. In some embodiments, external device 514 can be capable of processing and/or displaying one or both of image data from the imaging tool 510 and measurement data from test and measurement tool 500. In some examples, the external device 514 can be capable of acquiring image data from imaging tool 510 via wired or wireless communication link 588 and measurement data from test and measurement tool 500 via wired or wireless communication link 586.

The external device 514 can combine measurement data and image data for presentation on a display 516. In some examples, display 516 is built-in to the external device 514, such as a smartphone, tablet, laptop computer, etc. In other examples, the display 516 may be built-in to one of the imaging tool 510 and the test and measurement tool 500. For example, in some embodiments, image data from the imaging tool 510 is communicated to test and measurement 500 via communication link 584. In some such examples, the test and measurement tool 500 can combine the image data with measurement data for presentation on a display 516 either built-in to or otherwise in communication with the test and measurement tool 500. Similarly, measurement data may be communicated from the test and measurement tool 500 to the imaging tool 510 via communication link 584. The imaging tool 510 can combine the measurement data with acquired image data for presentation on display 516, which may be built-in to or otherwise in communication with imaging tool 510.

In some examples, the imaging tool 510 can include a fastener for temporary or permanent affixing to a location. Exemplary fasteners can include, for example, a magnet or a strap. Accordingly, in some examples, the imaging tool 510 can be affixed proximate a piece of equipment under test or to be tested (e.g., object 512) in order to acquire image data regarding the equipment from the imaging tool. The imaging tool can be configured to function independently, in conjunction with, or physically connected to the test and measurement tool 500. In some examples, the imaging tool 510 also can function in conjunction with, or controlled by another external device 514.

In general, systems such as shown in FIG. 5 may include any number of imaging tools and/or test and measurement tools. For example, a plurality of imaging tools may be used to acquire image data of an object under test from multiple perspectives or using multiple imaging techniques. Additionally or alternatively, a plurality of test and measurement tools may be used to determine a plurality of parameters of the object under test. Image data and measurement data from any number of imaging tools and test and measurement tools may be communicated to a central location (e.g., a single imaging tool, test and measurement tool, external device, etc.) for performing any of processing, combining, and displaying the acquired data.

In some embodiments, various system components may be used to control or otherwise interact with other components. For instance, in some embodiments, a user may interact with the imaging tool (e.g., 110) via test and measurement tool (e.g., 100). In some such examples, a user may control properties of the imaging tool, initiate an image capture, initiate data communication, view acquired image data, or perform other functions available on the imaging tool. Similarly, in some embodiments, a user may interact with a test and measurement tool via an imaging tool. For example, a user may similarly, via an imaging tool, control properties of the test and measurement tool, initiate a measurement, initiate data communication, view acquired measurement data, and the like.

In some examples, some or all of available control features (e.g., the ability to perform a function on one device using another) may be performed via a wireless communication. In some examples, certain functions may only be performed when the imaging tool and the test and measurement tool are physically coupled. For example, in some embodiments, performing various functions of the imaging tool via the test and measurement tool (or vice versa) may be available only when the imaging tool is received at the receiving portion (e.g., 102) of the test and measurement tool. In some such embodiments, certain communication options are made available via a physical connection to a communication port (e.g., 104). In an exemplary embodiment, with reference to FIG. 1C, engagement between imaging tool 160 and communication port 154 permits the test and measurement tool 150 to access image data from the imaging tool 160. In some examples, test and measurement tool 150 may access image data stored in memory of imaging tool 160 for presentation on the display 158.

Additionally or alternatively, external devices, such as a smartphone, tablet, PC, or the like may be used to similarly control or otherwise perform a function using one or both of the test and measurement tool and imaging tool. For example, the external device may initiate a measurement of a parameter of an object via the test and measurement tool and/or capturing of image data from the imaging tool (e.g., via communication link 586 or 588 of FIG. 5). Results of the initiated process may be communicated to the external device for processing and/or display.

In embodiments in which one or both of measurement data and image data are communicated to other devices, data processing may occur in any variety of locations. In some embodiments, measurement data communicated from the test and measurement tool may be processed by a different device, such as imaging tool or an external device. For example, unprocessed measurement data may be filtered, amplified, or otherwise processed into a desired signal by a separate device.

Similarly, in some embodiments, imaging tool may communicate unprocessed image data to a test and measurement tool or external device. The test and measurement tool or external device can be capable of performing any appropriate image processing techniques for generating an image from the image data. For example, image data may be filtered, amplified, blended, or processed via other known image processing techniques.

In various embodiments, the image data can include multiple sets of image data (e.g., IR and VL image data) that can be combined, manipulated, and presented, for example as described in U.S. Pat. No. 7,535,002, entitled “CAMERA WITH VISIBLE LIGHT AND INFRARED BLENDING,” which is assigned to the assignee of the instant application, and which is hereby incorporated by reference in its entirety. Additionally or alternatively, additional data, such as data acquired by the test and measurement tool (e.g., data acquired performing a primary measurement) or other communicating device, can be combined with image data (e.g., IR image data, VL image data, or a combination thereof) such as described in U.S. Patent Publication No. US20140278259, corresponding to U.S. patent application Ser. No. 14/214,600, filed Mar. 14, 2014, and entitled “CAPTURE AND ASSOCIATION OF MEASUREMENT DATA,” which is assigned to the assignee of the instant application, and which is hereby incorporated by reference in its entirety.

As described, one or both of image data and measurement data may be communicated to a variety of system components, such as imaging tool, test and measurement tool, and an external device. One or both of image data and measurement data may be processed or stored in memory at any of a variety of such locations. In some examples, image data and measurement data may be associated with one another. For example, measurement data may be indicative of at least one parameter of an object under test and image data may include data representative of an object under test during or otherwise near the time of acquiring the measurement data. Thus, the image data is representative of the object under test while in substantially the same condition reflected in the measurement data.

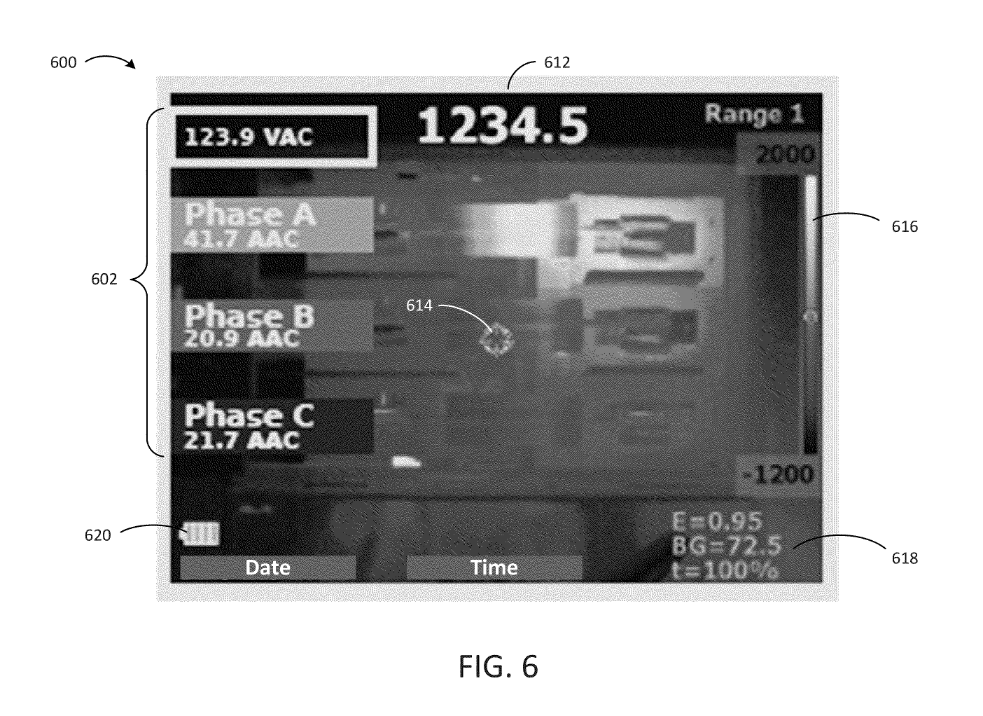

In some examples, associated image and measurement data can be processed to generate a display comprising both the image data and the measurement data for presentation to a user such as is shown in FIG. 6. FIG. 6 is an exemplary display showing combined image and measurement data. In the illustrated example, the display 600 includes measurement data 602 comprising a measurement of current flowing through three conductors and a measured voltage. In some examples, measurement data 602 may be acquired from a single test and measurement tool capable of measuring both current and voltage. In other examples, measurement data 602 comprising both voltage and current data may be acquired from a plurality of test and measurement tools, such as a volt meter and an ammeter or other current measuring device.

In still further embodiments, known information regarding the object under test may be used to supplement measurement data. For instance, if the resistance values of the conductors of FIG. 6 are known, voltage or current measurements may be used to calculate the other. In some such examples, supplementary information such as resistance values may be stored in memory or input by a user via a user interface, for example in response to a prompt.

In the illustrated embodiment, image data presented on the display includes infrared image data representative of the thermal pattern across the scene. In the illustrated example, the display 600 includes temperature information 612 representative of the temperature of a selected spot 614 on the display. In some examples, a user may adjust the location of spot 614 for displaying a temperature of an area of interest. The display 600 includes a temperature scale 616 that associates colors within a palettized IR image to corresponding temperature values. Any appropriate palettization scheme may be used, such as grayscale, red-blue, ironbow, amber, and others. The temperature scale 616 may be used to provide an indication to a viewer of the temperature of various points in the scene without requiring the placing of spot 614 over each point.

In some embodiments, other data 618 can be included in the display. Such data can include supplementary information for the image data (e.g., an emissivity value) or the measurement data. Other information that can be displayed include battery life information 620 or information data received from one or more other devices (e.g., test and measurement tools, imaging tools, etc.) or a network such as the internet. In various examples, such data can include information from specifications, FAQs, operating instructions, and the like.

In various embodiments, one or both of the location or content of displayed data is predetermined based on which devices are in communication. For instance, in one example, any acquired data (e.g., at least one parameter from the test and measurement tool, image data from the imaging tool, etc.) can be displayed on the test and measurement tool by default. In another example, any acquired data is automatically displayed on an external device if one is in communication with one or both of the test and measurement tool or the imaging tool. In some embodiments, a user can define what information is displayed on which devices. In some such embodiments, the user can make a selection via a user interface on any of the test and measurement tool, the imaging tool, or an external device regarding the type and location of displayed data using any of the available devices in communication with the system (e.g., test and measurement tool, imaging tool, external device, etc.).

Various embodiments have been described. Such examples are non-limiting, and do not define or limit the scope of the invention in any way. Rather, these and other examples are within the scope of the following claims.

1. A measurement system comprising:
a test and measurement tool, the test and measurement tool capable of performing at least one measurement to acquire measurement data representative of at least one parameter of an object;
an imaging tool removably attachable to the test and measurement tool, the imaging tool capable of detecting infrared radiation from a target scene and producing infrared image data;
at least one display in communication with one or both of the test and measurement tool and the imaging tool; and
a communication link capable of providing communication between the test and measurement tool and the imaging tool; wherein
(i) the imaging tool is configured to receive measurement data from the test and measurement tool via the communication link and to display the measurement data and infrared image data simultaneously;
(ii) the test and measurement tool is configured to receive infrared image data from the imaging tool via the communication link and to display the infrared image data and measurement data simultaneously; or
both (i) and (ii).

2. The measurement system of claim 1, wherein the test and measurement tool comprises one or more from the group consisting of: a digital multimeter, a current measurement tool, a power quality tool, a vibration tool, a portable oscilloscope tool, a laser alignment tool, an ultrasonic test tool, an insulation resistance tester, a multi-function electrical test tool, a single-function electrical test tool, a contact temperature measurement tool, a humidity measurement tool, an air-flow measurement tool, an air temperature measurement tool, and an air quality and particulate measurement tool.

3. The measurement system of claim 1, wherein the communication link is a wireless link.

4. The measurement system of claim 1, wherein at least one of the test and measurement tool and the imaging tool is configured to communicate data to an external device, such that the at least one of the measurement tool and the imaging tool is capable of communicating measurement data and infrared image data to the external device.

5. The measurement system of claim 4, wherein the display is disposed on the external device.

6. The measurement system of claim 4, further comprising a user interface by which a user can select a location in which to display at least one of the measurement data or the infrared image data.

7. The measurement system of claim 6, wherein the user interface allows a user to determine which type of data is displayed.

8. The measurement system of claim 1, wherein the imaging tool includes an infrared sensor array and a visible light sensor array.

9. The measurement system of claim 8, wherein the infrared sensor array and the visible light sensor array are configured to respectively generate infrared image data and visible light image data representative at least overlapping target scenes.

10. A method of analyzing an object under test comprising:
measuring at least one parameter of the object under test via a test and measurement tool to generate measurement data representative of the at least one parameter;
receiving electromagnetic radiation from a target scene via an imaging tool of the measurement system to generate image data of the object under test;
communicating the measurement data and the image data to a common location;
combining the measurement data and the image data; and
displaying a representation of the at least one parameter of the object under test and the image data of the object under test simultaneously.

11. The method of claim 10, wherein the image data of the object under test comprises infrared image data.

12. The method of claim 11, wherein the image data of the object under test further comprising visible light image data.

13. The method of claim 10, wherein communicating the measurement data and the image data to a common location comprises:
(i) transferring the measurement data from the test and measurement tool to the imaging tool;
(ii) transferring the image data from the imaging tool to the test and measurement tool; or
(iii) transferring the image data from the imaging tool to an external device and transferring the measurement data from the test and measurement tool to the separate device.

14. The method of claim 13, wherein the communicating the measurement data and the image data to a common location is done wirelessly.

15. An analysis tool comprising:
a test and measurement tool configured to acquire measurement data representative of at least one parameter of an object;
an imaging tool comprising at least one sensor array and configured to receiving radiation from a target scene and generate image data representative of the target scene;
a receiving portion configured for removably receiving the imaging tool; and
a communication link configured to provide one or both of:
(i) communication of image data from the imaging tool to another device and
(ii) communication of measurement data from the test and measurement tool to another device.

16. The analysis tool of claim 15, wherein the communication link is a wireless communication link.

17. The analysis tool of claim 15, wherein
(i) the communication of image data from the imaging tool to another device comprises communicating image data to the test and measurement tool; or
(ii) the communication of measurement data from the test and measurement tool to another device comprises communicating measurement data to the imaging tool.

18. The analysis tool of claim 15, wherein the communication of image data from the imaging tool to another device comprises communicating image data to an external device and the communication of measurement data from the test and measurement tool to another device comprises communicating measurement data to the external device.

19. The analysis tool of claim 15, further comprising:
a display; and
a processor configured to receive measurement data and image data and combine the received measurement data and image data to present a visual representation of the measurement data and the image data on the display.

20. The analysis tool of claim 19, wherein the imaging tool is integrated in the test and measurement tool and wherein the communication of image data from the imaging tool to another device comprises communicating image data to the test and measurement tool.
